(19) United States
(12) Patent Application Publication
(10) Pub. No.: US 2024/0164219 A1
(43) Pub. Date: May 16, 2024

(54) FAST SWITCHING MRAM HAVING AN ALUMINUM-MANGANESE-GERMANIUM FREE LAYER COMBINED WITH A CHROMIUM DIFFUSION BARRIER

(71) Applicant: International Business Machines Corporation, Armonk, NY (US)

(72) Inventors: Matthias Georg Gottwald, Ridgefield, CT (US); Alexander Reznicek, Troy, NY (US)

(21) Appl. No.: 17/985,804

(22) Filed: Nov. 11, 2022

(51) Int. Cl. H01L 43/08; H01L 27/22; H01L 43/02; H01L 43/10; H01L 43/12

(52) U.S. Cl. CPC H01L 43/08; H01L 27/222; H01L 43/02; H01L 43/10; H01L 43/12

(57) ABSTRACT

Embodiments of the present invention an (or an array of) magnetic tunneling junction (MTJ) pillars, each with a magnetic free layer (containing a fast-switching material like aluminum or a metal like gallium), a magnetic reference layer, and a tunnel barrier layer separating the two magnetic layers. A chromium-containing diffusion barrier layer disposed between the magnetic free layer and tunnel barrier layer prevents aluminum (or gallium) diffusion from the magnetic free layer into a tunnel barrier layer of the MTJ pillar. Devices using and methods of making the fast-switching MTJ(s) are also disclosed. The invention enables devices with reduced resistance area (RA). Embodiments use a AlMnGe alloy to make the magnetic free layer with a tetragonal crystalline structure and a lower magnetic moment that supports higher magnetic orientation switching speeds.

### BACKGROUND

The present invention relates to Magnetic Tunnel Junction (MTJ) devices, methods of making these MTJ devices, and uses of these MTJ devices in Magnetic Random-Access Memories (MRAM). More specifically, the invention relates to MTJ devices comprising materials and crystal structures in the MTJ free layer and materials in the tunneling barrier layer combined with a diffusion barrier layer that reduces MTJ device resistance and increases MTJ device switching speed.

MTJ device pillars are used in MTJ devices like MRAM, as well as in other MTJ devices. MRAM is a non-volatile random access memory technology in which data is stored using magnetic storage elements in the MTJ pillars. MRAM is a viable memory option for stand-alone and embedded applications, for example, cache, eDRAM replacement, the internet of things (IoT), automobiles, or artificial intelligence (AI).

MTJs are generally formed from two ferromagnetic layers, each of which can hold a magnetization. These magnetization layers are separated by a thin dielectric layer, i.e., the tunnel barrier layer. Embodiments of MTJs used as memory devices or sensors operate with one of the magnetic layers with an unchanged magnetization orientation during operation (the reference layer) while the magnetization orientation of the other layer (the free layer) may be modified or changed during operation.

In general, the magnetic orientation of the reference layer is set during an initiation process of the magnetic tunnel junction device, for example by exposure to a strong external magnetic field. In some cases, a strong magnetic field is combined with heat under ultra-high vacuum, e.g., exposure to a strong magnetic field greater than 0.1 Tesla, but in most MRAM cases probably greater than 1.5 Tesla; with heat applied at greater than 200 C but less than 550 C; and in an ultra-high vacuum of less than 10⁻⁵ Torr.

In more specific embodiments, a magnetic tunnel junction (MTJ) device is small dimensional MTJ pillar (with a typical diameter between 15-150 nanometers (nm), but more typically between 20-100 nm in diameter) comprising a magnetic reference layer, a magnetic free layer, and a thin tunnel barrier layer separating the magnetic reference layer and free layer.

A particular use case for MTJ devices is their implementation as physical bits of a magnetic random-access memory. In this use, a “0” and “1” are encoded as parallel and antiparallel magnetization states of the free layer and reference layer. A small sensing voltage applied to the ends of the pillar MTJ device enables measuring resistance of the MTJ pillar.

The tunneling-magneto resistance effect (TMR) provides a resistance difference between parallel and antiparallel orientation of the free and reference layer of the MTJ pillar. This resistance difference is used to indicate a bit value of the memory.

Different methods of writing to the bit exist for different memory designs. One method is the use of a write current flowing through the MTJ pillar generating a so-called spin transfer torque (STT). The direction of this write current with respect to the pillar geometry determines if a “0” or a “1” is written through reorientation of the free layer magnetization. The “direction of the write current with respect to the pillar geometry” is determined by whether the voltage across the tunnel barrier layer of the MTJ pillar is positive or negative.

In some typical MTJ stacks, the reference layer is in direct contact with the tunnel barrier layer. Tunnel barrier layers are often made of magnesium oxide (MgO). In some embodiments, the free layer typically consists of a combination of cobalt-iron-boron alloy (CoFeB) and cobalt-iron (CoFe) alloys combined with refractive metal layers like tantalum (Ta), tungsten (W), niobium (Nb), zirconium (Zr), or others.

MTJ pillar structures are usually formed by patterning and etching a blanket film of MTJ layers, where the blanket film of MTJ layers is in the form of a MTJ stacked structure. In some embodiments, the MTJ stacked structure is etched, e.g., by an ion beam etch (IBE), to form single MTJ pillars or arrays of one or more MTJ pillars. Devices, e.g., MRAMs, and other devices, can be made by connecting device components (like MRAM structures) in back-end-of-the-line (BEOL) levels to the MTJ pillars. These structures and methods of making these structures are known.

Advanced applications require random-access memories (RAM) with very fast switching times. Classes of MRAM called spin-transfer torque MRAM (STT MRAM) devices require switching times less than 10 nanoseconds (ns). In some applications, like last level cache or eDRAM replacement, switching times around 2 ns are required.

However, traditional MTJ or MRAM layer materials, like CoFeB or CoFe alloys, do not support high switch speeds because these materials have magnetic moments that are too high.

A tetragonal aluminum-manganese-germanium (AlMnGe) alloy (with element ratios of 1:1:1) is one promising material that provides required magnetic properties to use in MTJ free layers and enable high switching speeds.

However, the aluminum (Al) in the AlMnGe alloy causes a problem. When an AlMnGe ordered alloy free layer is in immediate contact with a MgO tunnel barrier layer during the thermal cycles of processing the MTJ stack, some of the aluminum from the AlMnGe diffuses into the MgO forming a MgAl-oxide. The problems resulting from this oxide formation include: 1. depleting the aluminum in the AlMnGe free layer, 2. changing the free layer magnetic properties, i.e., decreasing the magnetoresistance (tunneling magneto resistance—TMR), 3. increasing the barrier oxide electrical breakdown (TBBD), and 4. increasing the resistance area product (RA) of the stack.

To address these problems, the free layers have been given higher aluminum content, to compensate for the aluminum diffusion, and/or the MgO barrier layers have been made thinner. However, experiments have shown these efforts have failed to solve the problems.

There is a need to suppress the interaction of MTJ (free) layers containing aluminum (Al) with the MgO in MTJ barrier layers without adversely affecting the magnetic MTJ stack properties.

### SUMMARY

Embodiments of the present invention include at least one magnetic tunneling junction (MTJ) pillar with a magnetic free layer made of an aluminum-containing or gallium-containing, fast-switching material and a thin diffusion barrier layer made of elemental chromium that prevents aluminum (or gallium) diffusion from a magnetic free layer into a tunnel barrier layer of the MTJ pillar. Devices using and methods of making the fast-switching MTJ pillar(s) are also disclosed.

Embodiments of the pillar include one or more magnetic reference layers which are disposed on a substrate. (Other layers or structures, like back-end-of-the-line (BEOL) structures/layers, can be located between the magnetic reference layers and the substrate.) The magnetic reference layers have a first magnetic orientation. The first magnetic orientation is generally in a fixed magnetic orientation.

The magnetic free layer has a second magnetic orientation. The second magnetic orientation is switchable to be either in a parallel or anti-parallel alignment with the first magnetic orientation. In preferred embodiments, the magnetic free layer comprises a AlMnGe alloy, with atomic ratios of 1:1:1, in a tetragonal crystalline structure, having a lower magnetic moment to support higher switching speeds. Some embodiments of the magnetic free layer are made of gallium (Ga) alloys, including but not limited to GaMnGe.

A tunnel barrier layer, with a tunnel barrier layer thickness, separates the magnetic reference layer and the magnetic free layer. Current tunnels through the tunnel barrier layer when flowing between the magnetic reference layers and the magnetic free layers. When the magnetic reference layers and the magnetic free layers are in parallel alignment, the device is in a low resistance state. When the magnetic reference layers and the magnetic free layers are in anti-parallel alignment, the device is in a high resistance state. In preferred embodiments, the tunnel barrier layer is made of Magnesium oxide (MgO).

A diffusion barrier layer is disposed between the magnetic free layer and the tunnel barrier layer.

In one embodiment, the diffusion barrier layer is made of a thin chromium diffusion barrier layer (on the order of one to five atomic monolayers of thickness) made of elemental chromium. Other thicknesses are envisioned. In one embodiment, the thin layer chromium barrier layer interfaces and is direct contact with the tunnel barrier layer and prevents aluminum (or materials like gallium) from diffusing from the magnetic free layer into a tunnel barrier layer of the MTJ pillar.

In some embodiments, the diffusion barrier layer is an atomic monolayer thickness of chromium that is a face (interfacing face) of a tetragonal unit cell, i.e., the interfacing unit cell (with the tunnel barrier layer), of the free layer. In other embodiments, the diffusion barrier layer thickness can be between 0.2 nanometers (nm) and 1 nm or alternatively one to five atomic monolayer thickness of chromium.

In some embodiments, the diffusion barrier layer is in direct contact with the tunnel barrier layer. In preferred embodiments, the diffusion barrier layer (layer of chromium) is in direct contact (and between) both the tunnel barrier layer and free layer.

In some embodiments, the diffusion barrier layer is formed by incorporating chromium atoms into the interfacing face of the interfacing unit cell to form a tetragonal CrAlMnGe alloy, where Cr replaces Mn in the interfacing face. In a preferred embodiment, the chromium atoms are only in or only include the interfacing face and there are no chromium atoms elsewhere in the free layer.

The diffusion barrier layer has two sides or surfaces: 1. a “tunnel interface” being the side/surface in contact with the tunnel barrier layer, and 2. a “free layer interface” being the side/surface in contact with the free layer. Thus, the tunnel interface and the free layer interface are opposite surfaces of and across from one another on the diffusion barrier layer.

To summarize, the diffusion barrier layer is a chromium metal layer directly interfacing with and between the tunnel barrier layer and the tetragonal unit cells of the free layer. In one embodiment, the diffusion barrier layer is a layer on the order of an atomic monolayer of thickness containing only chromium atoms. The tunnel interface is the side/surface of the diffusion barrier layer that interfaces with the tunnel barrier layer and the free layer interface is the side/surface of the diffusion barrier layer that interfaces with free layer. The free layer contains no chromium atoms.

### BRIEF DESCRIPTION OF THE DRAWINGS

Various embodiments of the present invention will be described below in more detail, with reference to the accompanying drawings, now briefly described. The Figures show various apparatus, structures, and related method steps of the present invention.

FIG. 1 is a cross-sectional view of a non-limiting example of an interim magnetic tunnel junction (MTJ) stacked structure including a diffusion barrier layer between a MgO tunnel barrier layer and an aluminum-containing, AlMnGe, (or gallium-containing, e.g., MnGaGe) magnetic free layer.

FIG. 2 is a cross-sectional view of an example MTJ pillar that includes a diffusion barrier layer interfacing and between the MgO tunnel barrier layer and an aluminum-containing, AlMnGe, or gallium containing, MnGaGe, magnetic free layer.

FIG. 3 is a diagram showing the diffusion barrier layer interfacing the tunnel barrier layer and the free layer, where the exemplary magnetic free layer is a stacked tetragonal crystalline unit cell structure of AlMnGe alloy.

FIG. 4 is a cross-sectional view of an array embodiment of MTJ pillars on a substrate.

FIG. 5 is a graph showing the resistance area product (RA) of three MTJ structures with tunnel barrier layers made of MgO of the same thickness and free layers as follows: a) an AlMnGe free layer with no chromium, b) an AlMnGeCr alloy free layer with chromium throughout the free layer, and c) an AlMnGe free layer with a diffusion barrier layer (preferably an atomic monolayer of chromium thick), interfacing and between the free layer and the tunnel barrier layer.

FIG. 6 is a flow chart of a process of making a fast-switching MTJ including embodiments of deposition of a diffusion barrier layer between a MgO tunnel barrier layer and the AlMnGe magnetic free layer.

### DETAILED DESCRIPTION

It is to be understood that embodiments of the present invention are not limited to the illustrative methods, apparatus, structures, systems and devices disclosed herein but instead are more broadly applicable to other alternative and broader methods, apparatus, structures, systems and devices that become evident to those skilled in the art given this disclosure.

In addition, it is to be understood that the various layers, structures, and/or regions shown in the accompanying drawings are not drawn to scale, and that one or more layers, structures, and/or regions of a type commonly used may not be explicitly shown in a given drawing. This does not imply that the layers, structures, and/or regions not explicitly shown are omitted from the actual devices.

In addition, certain elements may be left out of a view for the sake of clarity and/or simplicity when explanations are not necessarily focused on such omitted elements. Moreover, the same or similar reference numbers used throughout the drawings are used to denote the same or similar features, elements, or structures, and thus, a detailed explanation of the same or similar features, elements, or structures may not be repeated for each of the drawings.

The semiconductor devices, structures, and methods disclosed in accordance with embodiments of the present invention can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, expert and artificial intelligence systems, functional circuitry, neural networks, etc. Systems and hardware incorporating the semiconductor devices and structures are contemplated embodiments of the invention.

As used herein, “height” refers to a vertical size of an element (e.g., a layer, trench, hole, opening, etc.) in the cross-sectional or elevation views measured from a bottom surface to a top surface of the element, and/or measured with respect to a surface on which the element is located.

Conversely, a “depth” refers to a vertical size of an element (e.g., a layer, trench, hole, opening, etc.) in the cross-sectional or elevation views measured from a top surface to a bottom surface of the element. Terms such as “thick”, “thickness”, “thin” or derivatives thereof may be used in place of “height” where indicated.

As used herein, “lateral,” “lateral side,” “side,” and “lateral surface” refer to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

As used herein, terms such as “upper”, “lower”, “right”, “left”, “vertical”, “horizontal”, “top”, “bottom”, and derivatives thereof shall relate to the disclosed structures and methods, as oriented in the drawing figures. For example, as used herein, “vertical” refers to a direction perpendicular to the top surface of the substrate in the elevation views, and “horizontal” refers to a direction parallel to the top surface of the substrate in the elevation views.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop,” “disposed on,” or the terms “in contact” or “direct contact” means that a first element and a second element are connected without any intervening elements, such as, for example, intermediary conducting, insulating or semiconductor layers, present between the first element and the second element.

It is understood that these terms might be affected by the orientation of the device described. For example, while the meaning of these descriptions might change if the device was rotated upside down, the descriptions remain valid because they describe relative relationships between features of the invention.

A magnetic tunnel junction (MTJ) has two magnetic, electrically conductive, metal layers separated by a thin layer of insulator, a tunnel barrier layer. The tunnel barrier layer is thin enough so that electrons can tunnel through the tunnel barrier if a bias voltage is applied between two metal electrodes or connections attached to the respective magnetic metal layers. In some embodiments, the bias voltage is applied through connections in a BEOL layer.

In MTJs, the tunneling current magnitude depends on the relative orientation of the magnetization of the two magnetic layers. When the magnetic layers are magnetized in the same direction, i.e., in parallel alignment or parallel orientation, more tunneling current flows, therefore the resistance of the device decreases, and the device is in a low resistance state. On the other hand, when the magnetic layers are magnetized in opposite directions/orientation, i.e., in antiparallel magnetization or antiparallel orientation, less tunneling current flows, therefore the resistance of the device increases, and the device is in a high resistance state.

In some embodiments, one of the magnetic layers acts as a “fixed layer” or “reference layer”, whose magnetization direction is fixed to a given direction. Alternatively, the other magnetic layer acts a “free layer”, whose magnetization changes its direction relatively easily with respect to the “fixed” or “reference” layer.

Based on the relative magnetic orientations of free layer with respect to reference layer, the device is switched from parallel alignment to antiparallel alignment and visa-versa. As a result, the resistance of the device is switched from a high resistance state to a low resistance state and visa-versa.

During operation of the device in some embodiments, a switching current with a current magnitude above a switching magnitude threshold is used to switch the magnetization orientations of the magnetic free layer. For example, a switching current above a switching magnitude threshold in a direction from the reference layer to the free layer (across the tunnel barrier) switches the magnetization direction of the free layer with respect to the reference layer from parallel to antiparallel. Alternatively, a switching current above a switching magnitude threshold in a direction from the free layer to the reference layer (across the tunnel barrier) switches the magnetization direction of the free layer with respect to the reference layer from antiparallel to parallel. In this manner, the magnetization direction of the magnetic free layer can be switched from parallel to antiparallel alignment, and visa-versa with respect to the magnetization direction of the magnetic fixed layer. A sensing current, with lower magnitude, passed through the device in either direction will sense whether the device is in a low or high resistance state.

It is noted that in some embodiments, the magnetic fixed and/or reference layer can be formed in one or more magnetic layers.

A diffusion barrier layer, i.e., a diffusion barrier layer made of chromium, separates the tunnel barrier layer and the magnetic free layer whereby the diffusion barrier layer prevents aluminum (or other substances like gallium) from diffusing into the tunnel barrier layer from the magnetic free layer (free layer).

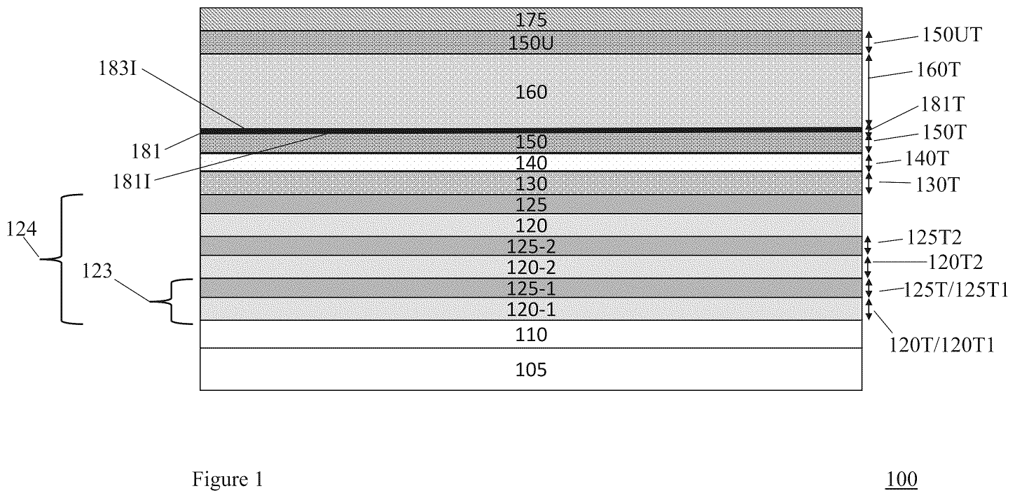

FIG. 1 is a cross-sectional view of an interim magnetic tunnel junction (MTJ) stacked structure 100 built on a substrate 105.

An exemplary substrate 105 can be made from a single element (e.g., silicon or germanium) or a compound semiconductor, for example, gallium arsenide (GaAs), or a semiconductor alloy, for example silicon-germanium (SiGe). The substrates 105 for these devices are well known and varied. Further, substrates 105 can be as simple as a single dielectric layer or as complex as known front end of the line (FEOL) circuitry. Alternative substrates 105 are known in the art and are envisioned.

The back end of the line (BEOL) layer or structure 110 is disposed on the substrate 105 and includes a well-known plurality of layers formed by well-known BEOL processes performed in semiconductor technologies. Note, as is well known, BEOL “layers” typically include contacts, components, connections, vias, insulating layers and metallization and interconnection layers which have a form that is different than the layers referred to in the other “layers” in the stacked structure 100. One skilled in the art would know how to distinguish “layers” in the BEOL from other layers of the stacked structure 100, e.g., based on the context of the description. Layers in the BEOL 110 will be referred to as BEOL layers (or in aggregate the BEOL layer or structure 110) to aid in this distinction between the layers, even though it is thought not necessary to make this distinction formally.

As is known, circuitry made in the FEOL layers can be connected to the MRAM or MTJ pillars (see element 250 below) with interconnect structures in the BEOL layer 110 and/or the substrate 105. In some embodiments, some MRAM circuitry is formed in the BEOL layer and this MRAM circuitry is connected to MTJ pillar (see 250 below) connections to complete MRAM device formation.

In some embodiments there is a single layer of ferromagnetic material 125 disposed on the BEOL layer 110. This layer of ferromagnetic material 125 is a magnetic reference layer 125 and is set to one magnetic polarity or orientation. In some embodiments, the reference layer 125 is a permanent magnet 125 or other fixed magnetic material. For example, the reference layer 125 may be composed of one or more metals or metal alloys exhibiting high spin polarization. Non-limiting examples of reference layer 125 metals and/or metal in alloys include: iron (Fe), nickel (Ni), cobalt (Co), chromium (Cr), boron (B), or manganese (Mn).

In alternative embodiments, the magnetic reference layer 125 is formed as a multilayer arrangement 123 having (1) a high spin polarization region formed from of a metal and/or metal alloy using the metals mentioned above 125/125-1 and (2) a region constructed of a material or materials that exhibit strong perpendicular magnetic anisotropy (strong PMA) 120/120-1. In some embodiments, the multilayer arrangement 123 is one pair of a single ferromagnetic material layer or high spin polarization layer 125 and a single PMA layer 120. In other embodiments, there are multiple pairs 124 of a high spin polarization layer 125-1 and a PMA layer 120-1 in the multilayer arrangement 124 of the magnetic reference layer 124. Exemplary materials with strong PMA 120/120-1 that may be used include metals such as cobalt, nickel, platinum, palladium, iridium, or ruthenium, and include these metals arranged as alternating layers. The strong PMA regions/layers may also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. In some embodiments, some or all layers with high spin polarization are omitted.

Again, the alloys may be arranged as alternating layers as shown in region 123 or in alternating layers 120/125 above region 123. In some embodiments, combinations of these materials and regions may also be employed. In these instances, the combination of layers 124 functions as the magnetic fixed layer 124 or magnetic reference layer 124. All these embodiments and their combinations are envisioned.

The thickness of magnetic reference layer (125, 120/125, 123, 124) will depend on the material selected. Example thicknesses 125T−1 of a high spin layer 125-1 and example thicknesses 120T1 of PMA layer 120-1 range between from 0.3 nanometers (nm) to 3 nm. However, other thicknesses are envisioned and the thicknesses (120T, 120T1, 125T, 125T1, etc.) depend on the material selected.

In alternative embodiments, only the polarization enhancing layer 140 (described below) has a high spin polarization and the high spin polarization is not essential for the other layers 124.

In some embodiments the magnetic reference layer 124 comprises a series of alternating layers 123 of a platinum (Pt) PMA layer 120 (120-1) and cobalt (Co) layers 125 (125-1) making up the magnetic fixed layer 124 which is disposed on the BEOL layer 110.

In some embodiments, having multiple layers in the reference layer 123/124 make the reference layer 123/124 more stable and reliable. Different configurations of reference layers 123/124 are known and envisioned as embodiments of this invention. For example, in some embodiments, the free layer(s) 160 can be deposited on the BEOL layer 110 first and afterwards the magnetic reference layer 124 can be deposited so the device would be “upside down” from the one depicted in FIG. 1 and the later Figures.

The reference layer(s) 123/124 are deposited by known techniques, e.g., physical vapor deposition (PVD), using known tools like a PVD cluster tool. Typically, multiple layers can be deposited using the same tool by using sub chambers to avoid breaking vacuum, as is well known.

In some embodiments, a non-magnetic spacer metal layer 130 is deposited on the reference layer(s) 123/124, e.g., using the PVD method described above. In some embodiments, the non-magnetic spacer metal layer 130 is made tantalum, tungsten, or other refractory metal and has a thickness 130T between 0.1 nanometers (nm) and 0.4 nm. In some embodiments, this layer 130 is omitted. These and other alternative embodiments of the non-magnetic metal layer 130 are envisioned.

In some embodiments, a polarization enhancing layer 140 is deposited on the non-magnetic spacer metal layer 130 using known techniques, e.g., PVD using the PVD cluster tool described above. In some embodiments, the polarization enhancing layer 140 is made of CoFeB or bilayer of CoFeB|Fe, with a total thickness 140T between 0.5 nm to 1.5 nm. In some embodiments, the polarization enhancing layer 140 has a thickness 140T of about 1 nm.

The tunnel barrier layer 150 is made of an insulator material and is formed at such a thickness as to provide an appropriate tunneling resistance. Exemplary materials for the tunnel barrier layer 150 include magnesium oxide (MgO). The thickness 150T of the tunnel barrier layer 150 will depend on the material selected. In one example, the tunnel barrier layer 150 may have a thickness 150T from 0.5 nm to 1.5 nm. The tunnel barrier layer 150 is deposited by known techniques including atomic layer deposition (ALD), physical vapor deposition (PVD), chemical vapor deposition (CVD). In preferred embodiments, the tunnel barrier layer 150 contains less than 5% aluminum, more preferably the tunnel barrier layer 150 contains 0% aluminum.

For most embodiments, MgO is the material preferred for the tunnel barrier layer 150 while materials like titanium oxide (TiO₂) are used but are less preferred. While MgO is the preferred material used for the tunnel barrier layer 150, all embodiments are contemplated as used for this invention. The preferred method of deposition for such MgO barrier layers is physical vapor deposition.

A diffusion barrier layer 181 comprises a thin (e.g., an atomic monolayer, the approximate thickness 181T of the diameter of a chromium atom or one to five atomic monolayers of thickness 181T) barrier layer 181 of chromium atoms. The diffusion barrier layer 181 is disposed on, interfaces, and is in direct contact with the tunnel barrier layer 150 at the tunnel interface 181I and is between the tunnel barrier layer 150 and the magnetic free layer 160. The diffusion barrier layer 181 interfaces and is in direct contact with the free layer 160 at the free layer interface 183I. Other diffusion barrier layer 181 thickness 181T are contemplated, as disclosed herein.

The chromium in the diffusion barrier layer 181 is what prevents aluminum (and in some embodiments, gallium) diffusion across the tunnel interface 181I from the magnetic free layer 160 into the tunnel barrier layer 150, even during manufacturing heat cycling steps during formation of the MTJ pillars.

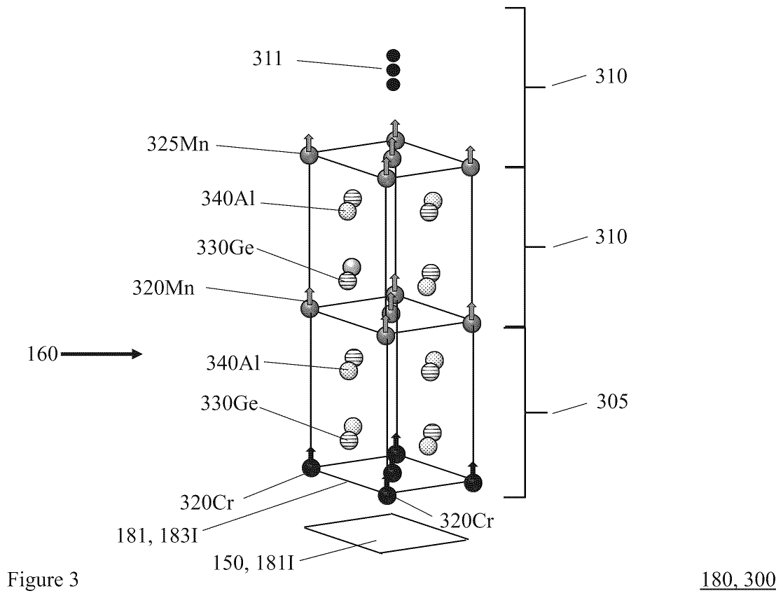

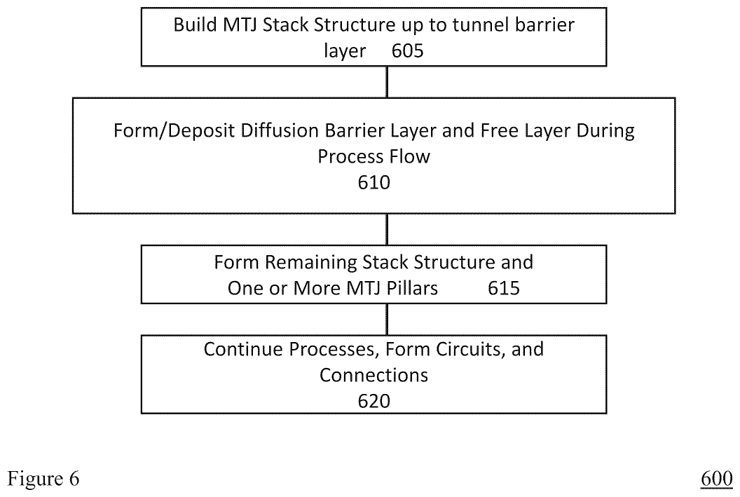

As is described in more detail below, in one embodiment, the diffusion barrier layer 181 is formed by depositing elemental chromium on the surface of the tunnel barrier layer 150 in a vacuum/inert gas environment to form a layer of chromium as an interfacing face of an interfacing unit cell of the free layer 160. The elemental chromium can be deposited by PVD in an ultrahigh vacuum (UHV) as described herein. For example, see FIG. 6. Use of the UHV and inert gas environment prevents the oxidation of the chromium and formation of electrically insulating chromium oxides. In some embodiments, the diffusion barrier layer 181 thickness 181T is the thickness of an atomic monolayer of chromium atoms or can range between 1 and 5 angstroms, or preferably between 2 and 3 angstroms. In other embodiments, the diffusion barrier layer 181 thickness 181T is between 0.2 nanometers (nm) and 1 nm or, alternatively, between 1 and five atomic layers of chromium atoms. See a more detail in the description of FIG. 3.

In one embodiment, the entire magnetic free layer 160 is deposited on the diffusion barrier layer 181 and therefore, as stated, the magnetic free layer 160 directly interfaces the diffusion barrier layer 181 at the free layer interface 183I so that the diffusion barrier layer 181 separates the tunnel barrier layer 150 and the magnetic free layer 160.

The magnetic free layer 160 material is a magnetic material (or a stack of magnetic materials) with a magnetization that can be changed in an orientation relative to the magnetization orientation of the magnetic material in the magnetic reference layer, 124 typically. In particular, the material in the magnetic reference layer 160 can switch at high speeds, e.g., at speeds higher than 10 ns, or more preferably between 2 ns and 5 ns. In a preferred embodiment the magnetic moment per area of the free layer is between 0.02 and 0.1 memu/cm2.

In some embodiments, the magnetic free layer 160 is made of material that contains aluminum, e.g., an aluminum-containing free layer 160. In still other embodiments, the aluminum-containing magnetic free layer 160 is made of an alloy of aluminum (Al), manganese (Mn), and germanium (Ge), typically with an atomic ratio of 1:1:1 between the Al, Mn, and Ge. In some embodiments, the magnetic free layer 160 is made of AlMnGe with a tetragonal crystalline symmetry.

In alternative embodiments, the magnetic free layer 160 can be made of Mn₂AlCo, MnAlCo₂, or MnAl. In additional alternative embodiments, the free layer 160, can contain a metal like gallium (Ga) and can be made of MnGaGe, Mn₂GaCo, MnGaCo₂, and MnGa.

In some embodiments, the magnetic free layer 160 thickness 160T is between 2 nm to 2.5 nm and is deposited by known techniques, e.g., as described above—PVD with a cluster deposition tool.

In some embodiments, an upper MgO layer 150U is deposited on the magnetic free layer 160 using the techniques and equipment described above. The upper layer 150U, e.g., MgO layer 150U, is made of a material (typically MgO) with a thickness 150UT that adds no (or negligible series resistance) through the stacked structure 100. However, this upper MgO layer 150U is optional and will be omitted in the remainder of this description without loss of generality.

(Note however, given this disclosure, one could add an optional chromium diffusion layer (not shown) between the upper MgO layer 150U and the magnetic free layer 160.)

A capping layer 175 is deposited as a final layer of the MTJ stacked structure 100. In some embodiments, the capping layer is made of a conductive metal that is used as an electrical contact/electrode for the device. Example, metals for the capping layer 175 include tantalum (Ta), Titanium (Ti), Tantalum Nitride (TaN), Titanium Nitride (TiN), ruthenium (Ru), tungsten (W), or any combination thereof. The capping layer 175 is deposited using known deposition techniques including PVD (e.g., as above), CVD, ALD, and sputtering. Various thicknesses are envisioned for the capping layer 175. In some embodiments, the capping layer 175 thickness is between 20 nm and 100 nm.

The capping layer 175 is used as an electrical connection for the device. In some embodiments, other electrical connections are made through the BEOL layer 110.

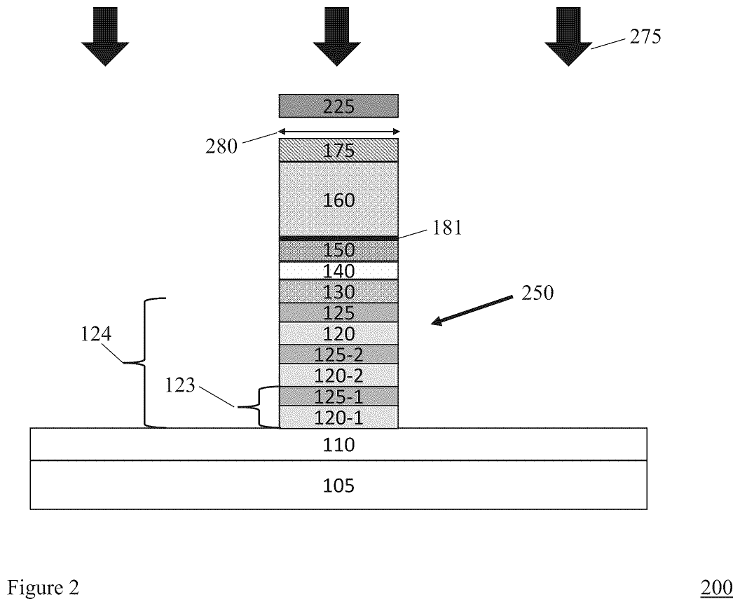

FIG. 2 is a cross-sectional view of a MTJ pillar 200/250 with the MTJ pillar magnetic free layer 160, the tunnel barrier layer 150, and the diffusion barrier layer 181.

A MTJ pillar 250 or arrays of two or more MTJ pillars 250 are created from one or more MTJ stack structures by performing a generally known masked 225 etching 275 process. A hard mask 225 is a protective, hard material deposited by standard techniques.

In some embodiments, the etching 275 is ion beam etching (IBE). The IBE is time controlled to stop once the surface of the BEOL layer 110 is reached by known techniques and creates MTJ pillars 250 in shapes and locations defined by the mask(s) 225. The widths 280 of the MTJ pillars 250 is in the range of 20 to 100 nm. The mask(s) 225 may be processed further by known methods.

FIG. 3 is a diagram showing the diffusion barrier layer 181 interfacing (for clarity not shown in direct contact) 181I the tunnel barrier layer 150 at the tunnel interface 181I and interfacing 183I the (magnetic) free layer 160 at the free layer interface 183I. The exemplary magnetic free layer 160 is an electrically conductive, stack 311 structure of tetragonal crystalline unit cells 305/310 of a AlMnGe alloy.

In one embodiment, the interfacing unit cell 305 of the magnetic free layer 160 includes the interfacing face 183I which functions as the diffusion barrier layer 181, with an atomic monolayer of thickness 181T. The interfacing face 183I of the interfacing unit cell 305 becomes the diffusion barrier layer 181 after the manganese atoms 320Mn in the interfacing face 183I are replaced with chromium atoms 320Cr. Accordingly, a monoatomic layer of elemental chromium 320Cr/181 is formed as the diffusion barrier layer 181 that interfaces 181I with the tunnel barrier layer 150 at the tunnel interface 181I and interfaces 183I with the magnetic free layer 160 at the free layer interface 183I.

The thickness 181I of the diffusion barrier layer 181 can be increased by depositing more chromium, e.g., in the process described in FIG. 6.

In a preferred embodiment, the unit cells 310 that are not interfacing unit cells 305, i.e., the non-interfacing unit cells 310, make up most of the magnetic free layer 160 thickness 160T. The non-interfacing unit cells 310 do not contain chromium.

The term “structure of tetragonal crystalline unit cells” denotes a crystal structure having unit cells containing three axes, two of which are of the same length and are at right angles to each other, and where the third axis is perpendicular to the other two axes. Tetragonal crystalline lattices result from stretching a cubic lattice along one of its lattice vectors, so the cube becomes a rectangular prism with a square base (e.g., sides x by x) and a height (y, which is different than x).

In some embodiments, as shown in FIG. 3, the plurality of stacked tetragonal crystalline unit cells (non-interfacing unit cells) 310 in the magnetic free layer 160 are made of a AlMnGe alloy 310. As an exception, the interfacing unit cell 305 in the magnetic free layer 160 is made of a CrAlMnGe alloy wherein Cr atoms 320Cr replace the Mn atoms 320Mn to form the diffusion barrier layer 181.

As stated, this diffusion barrier interfacing (chromium layer) 181 acts as a barrier for the diffusion of aluminum (Al) (or alternatively, gallium (Ga)) from the free layer 160/305/310 through the free layer interface 183I of the diffusion barrier layer 181 into the tunnel barrier layer 150.

It is thought that the chromium-containing diffusion barrier 181 will also prevent diffusion of materials other than aluminum from the free layer 160 into the tunnel barrier layer 150. For example, the chromium-containing interfacing unit cell 305 would prevent the diffusion of Gallium (Ga) from the free layer 160 to the tunnel barrier layer 150, where the free layer 160 was made of GaMnGe or other Ga-containing compounds.

As a continuing non-limiting example, the chromium-containing diffusion barrier 181 would prevent diffusion of Al into the tunnel barrier layer 150 in instances where the free layer 160 is made of Mn₂AlCo, MnAlCo₂, and MnAl. In addition, the chromium-containing diffusion barrier 181 would prevent diffusion of Ga into the tunnel barrier layer 150 in instances where the free layer 160 is made of Mn₂GaCo, MnGaCo₂, and MnGa.

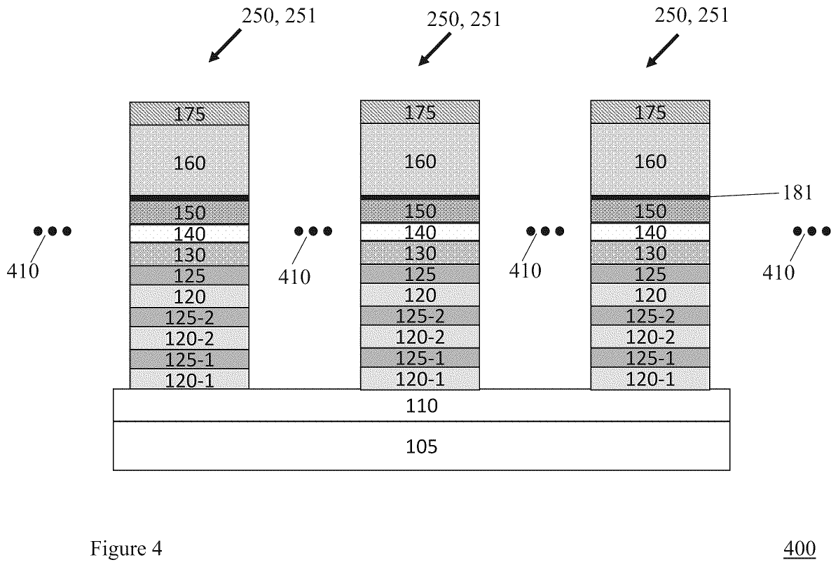

FIG. 4 is a cross-sectional view of an array 400 of MTJ pillars 250/251 on a substrate 105. The array 400 was created from the MTJ stacked structure 100 using the masked 225 patterned etch 275 techniques described above, e.g., in FIG. 2. Using these known techniques, arrays 400 of MTJ pillars 250/251 can be created extending 410 in both directions of the plane of the substrate/BEOL layers 105/110. MRAMs are created by forming connections to the MTJ pillars 250/251 and other components though the BEOL layers 110.

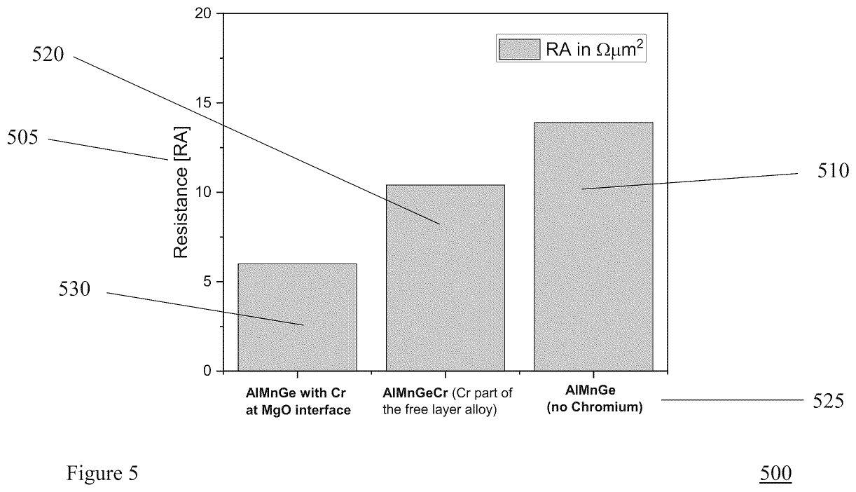

FIG. 5 is a graph 500 showing the resistance area product (RA, as measured in ohms-micro-meter², Ω-μm²) 505 of three MTJ structures 525 with tunnel barrier layers made of MgO of the same thickness and free layers as follows: a) an AlMnGe free layer with no chromium 510, b) an AlMnGeCr alloy free layer with chromium throughout the free layer 520, and c) an AlMnGe free layer with a diffusion barrier layer 181, interfacing and between the free layer and the tunnel barrier layer 530, as in the present invention.

As the graph 500 shows, the resistance area product, RA, 505 of the case 530 where there is a chromium diffusion barrier layer 181 is lower than both the other cases 510/520. The RA is on the order of 7 ohms-micro-meter², Ω-μm² or less where 530 there is a chromium diffusion layer 181.

As a result of the diffusion barrier layer 181 enabling a reduced RA for a given tunnel barrier layer 150 thickness 150T, the nominal thickness of the MgO tunnel barrier can be thicker when a diffusion barrier is present while not increasing the device resistance. A thicker barrier will be less prone to defects and the electric field across such a thicker barrier for a given voltage will be smaller. Less defects and less electrical field across the MgO barrier will make the barrier less likely to fail due to electric break down and extend the lifetime of the devices and the reliability of the memory formed by the MTJ pillar devices.

FIG. 6 is a flow chart of a process 600 of making a fast-switching MTJ 200/400 including a diffusion barrier layer 181 between a tunnel barrier layer 150 and an aluminum-containing (AlMnGe) (or other) magnetic free layer 160.

The process 600 begins with step 605 by building a MTJ stack structure 100 as described in the description of FIG. 1 until after the tunnel barrier layer 150 is deposited.

In step 610, the diffusion barrier layer 181 and free layer 160 are deposited, first by depositing a layer of elemental chromium 181 and next by growing the free layer 160 with no chromium.

The diffusion barrier layer 181 (see FIG. 3) is formed by depositing a layer of elemental chromium using PVD techniques and the PVD cluster tool described above. In some embodiments, this process step 610 is performed in a vacuum environment so that no oxides are formed and the diffusion barrier layer 181 remains electrically conductive. In some embodiments, the diffusion barrier layer 181 is sputtered using the PVD cluster tool in an environment of a noble gas, like argon (Ar) or krypton (Kr), or other noble gases, or in an environment of a mixture of noble gases. The sputtering can occur at room temperature for a time duration between 0.5 to 100 seconds, although other temperatures and time durations are contemplated. The sputtering continues until the desired diffusion barrier layer 181 thickness 181T is achieved.

After the element chromium is deposited, a Mn—Ge—Al alloy is deposited, typically in a 1:1:1 ratio, to form the interfacing unit cell 305 and remaining non-interfacing unit cells 310. The as deposited Mn:Ge:Al atomic ratios can deviate from 1:1:1 and allow for Mn:Al ratios of up to 1:2 and for Mn:Ge ratios of up to 1:1.5. As stated above, after the deposition of the chromium layer 181 interfacing the tunnel barrier layer 150, the interfacing unit cell(s) 305 and the free layer unit cells 310 are grown using the standard PVD techniques and the PVD cluster tool as described.

Enough of these non-interfacing units 310 are formed to achieve the desired thickness 160T of the magnetic free layer 160.

In step 615, the remainder of the MTJ stack structure is formed along with the MTJ pillar(s) 250, as described above.

In step 620, circuits, e.g., MRAMs, are formed by connecting the MTJ pillars 250/251 to circuitry, e.g., in BEOL layers 110, using known methods.

As a result of this process 600, and as shown in the description of FIG. 3, the chromium atoms 320Cr form the atomic monolayer chromium diffusion barrier layer 181 contained in the interfacing unit cell 305. The diffusion barrier layer 181 thickness 181T can be increased by depositing more chromium on the atomic monolayer of chromium.

The diffusion barrier layer 181 is effective in blocking the migration of aluminum (Al) and other metals, like germanium (Ge), into the tunnel barrier layer 150 while keeping the diffusion barrier layer 181 thin 181T. Accordingly, these metals can be used in the low magnetic moment magnetic free layer 160 to enhance device switching times without deteriorating the tunnel barrier layer 150.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. For example, the semiconductor devices, structures, and methods disclosed in accordance with embodiments of the present invention can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, expert and artificial intelligence systems, functional circuitry, etc. Systems and hardware incorporating the semiconductor devices are contemplated embodiments of the invention.

The terminology used herein was chosen to explain the principles of the embodiments and the practical application or technical improvement over technologies found in the marketplace or to otherwise enable others of ordinary skill in the art to understand the embodiments disclosed herein. Devices, components, elements, features, apparatus, systems, structures, techniques, and methods described with different terminology that perform substantially the same function, work in the substantial the same way, have substantially the same use, and/or perform the similar steps are contemplated as embodiments of this invention.

We claim:

1. A magnetic tunneling junction (MTJ) comprising:
a magnetic reference layer;
a magnetic free layer;
a tunnel barrier layer disposed between the magnetic reference layer and the magnetic free layer, and
a diffusion barrier layer with a diffusion barrier layer thickness, a tunnel interface, and a free layer interface, the diffusion barrier layer being disposed between the tunnel barrier layer and the magnetic free layer, the tunnel interface and free layer interface being opposite one another across the diffusion barrier layer, the diffusion barrier layer being made of elemental chromium, the tunnel interface being in direct contact with the tunnel barrier layer, and the free layer interface being in direct contact with the magnetic free layer,
wherein the diffusion barrier layer prevents one of aluminum and gallium from diffusing from the magnetic free layer into the tunnel barrier layer.

2. The MTJ, as in claim 1, wherein the magnetic free layer is made of AlMnGe.

3. The MTJ, as in claim 1, wherein the tunnel barrier layer is made from MgO.

4. The MTJ, as in claim 1, where the diffusion barrier layer thickness is between 0.2 nanometers (nm) and 1 nm.

5. The MTJ, as in claim 1, wherein the diffusion barrier layer thickness is a thickness of one atomic monolayer of chromium.

6. The MTJ, as in claim 1, wherein the diffusion layer thickness is a thickness between one and five atomic monolayers.

7. The MTJ, as in claim 1, wherein the diffusion barrier layer is electrically conductive.

8. The MTJ, as in claim 1, wherein the magnetic free layer is made of a stack of a plurality of tetragonal unit cells, including a plurality of non-interfacing unit cells disposed on an interfacing unit cell, the interfacing unit cell having an interfacing face, the interfacing face being the tunnel interface in direct contact with the tunnel barrier layer.

9. The MTJ, as in claim 8, where the interfacing unit cell is made of CrAlMnGe.

10. The MTJ, as in claim 8, where the non-interfacing unit cells are made of AlMnGe.

11. The MTJ, as in claim 8, where the non-interfacing unit cells do not contain chromium.

12. The MTJ, as in claim 1, where the tunnel barrier layer contains less than 5% aluminum.

13. The MTJ, as in claim 1, wherein the tunnel barrier layer is less than 1.5 nanometers (nm) thick.

14. The MTJ, as in claim 1, where the MTJ has a resistance area product (RA) between 2 and 25 ohms-micro-meter².

15. The MTJ, as in claim 1, where the magnetic free layer is made of one of the following: Mn₂AlCo, MnAlCo₂, AlMnGe, and MnAl.

16. The MTJ, as in claim 1, where the magnetic free layer is made of one of the following: Mn₂GaCo, MnGaCo₂, MnGa, and MnGaGe.

17. The MTJ, as in claim 1, that is one of the MTJs in array of MTJs.

18. A method of making a magnetic tunneling junction (MTJ) comprising the steps of:
building an MTJ stack structure up to a tunnel barrier layer;
forming a diffusion barrier layer containing chromium on the tunnel barrier layer;
forming a magnetic free layer on the diffusion barrier layer; and
etching the MTJ stack structure to form one or more MTJ pillars.

19. The method, as in claim 18, wherein the diffusion barrier layer is a layer of chromium one to five atomic monolayers thick.

20. The method, as in claim 18, where a plurality of non-interfacing unit cells in the magnetic free layer contains no chromium.
